(19) United States
(12) Patent Application Publication
(10) Pub. No.: US 2026/0239748 A1
(43) Pub. Date: Aug. 13, 2026

(54) DURABLE PHOTOVOLTAIC MODULES STABILIZED BY COMBINATION ENCAPSULANTS

(71) Applicant: SAUDI ARABIAN OIL COMPANY, Dhahran (SA)

(72) Inventors: Konstantinos KOTSOVOS, Dhahran (SA); Abdullah BAKHSHWIN, Dhahran (SA); Joao TAVARES, Dhahran (SA); Anas BINTIN, Dhahran (SA); Marwan ABDULLAH, Dhahran (SA); Ali BASAHEEH, Dhahran (SA)

(73) Assignee: SAUDI ARABIAN OIL COMPANY, Dhahran (SA)

(21) Appl. No.: 19/051,992

(22) Filed: Feb. 12, 2025

(51) Int. Cl. H10F 19/80

(52) U.S. Cl. CPC H10F 19/804

(57) ABSTRACT

Compositions and methods for constructing a photovoltaic (PV) module bound by multiple layers of encapsulant as well as a custom lamination protocol. Various embodiments described herein include a PV apparatus comprising transparent polycarbonate (PC) plates containing a silicon solar power cell bound with a novel multilayer encapsulation polymers encompassing each side of the solar power cell, where the multilayer encapsulation polymers are in contact with the PC plate surface and the solar power cell surface. The multilayer encapsulant comprises an encapsulation polymer first layer and a second layer, where the first layer is a first thermoplastic polyurethane (TPU) layer that is in contact with a second layer comprising an additional encapsulation polymer.

### FIELD OF THE DISCLOSURE

The present disclosure generally relates to solar panels comprising polycarbonate outer layers, and methods of manufacturing same.

### BACKGROUND OF THE DISCLOSURE

Renewable energy sources, such as solar energy, are necessary for reducing greenhouse gas emissions and mitigating climate change as major industrial nations strive to establish carbon-free electricity grids. Recent advancements in solar energy have included greater efficiency of solar cell conversion, incorporation of more abundant materials, flexible apparatus design, decrease in cost, and advancements in manufacturing techniques. Solar photovoltaic (PV) modules, commonly known as solar panels, are popular apparatus that convert direct and reflected sunlight into electricity. Solar cells within the PV modules struck by solar rays are made up of a semiconductor material such as silicon, generating electricity via the photovoltaic effect. The photovoltaic effect is a process that generates voltage or an electrical current within the semiconductor material of the solar panel when struck by light. Photons (bundles of electromagnetic radiation or energy) are absorbed by the solar cell and induce a flow of electrons into an external circuit. PV modules have operable lifetimes of at least 20 years and are designed to withstand a wide range of harsh climate conditions like heavy winds and rain. These modules are fabricated as sealed, weatherproof enclosures with the adhesion of solar cells to tempered transparent or semi-transparent protective plating such as glass.

Traditionally, the outer structure of the PV module is a tempered glass coated for UV stabilization and abrasion resistance. However, glass is heavy and has low impact resistance, and makes the PV module overly rigid. It would be useful to replace the glass with a flexible polymer material that would reduce weight and increase impact resistance, such as a thermoplastic polymer.

However, the manufacturing of PV modules is plagued by numerous inefficiencies, particularly the sealing of the enclosure to maintain environmental stability. Current sealants, or encapsulants, such as ethylene vinyl acetate (EVA) adhere well between glass plating and solar cells. But EVA encapsulant binding with polymer plates have lower adhesion strength and less resistance to environmental volatility. Therefore, it is imperative to find more efficient encapsulant methods and/or compositions to properly protect PV modules from humidity and provide environmental stability for solar panel longevity.

### SUMMARY OF THE DISCLOSURE

Various details of the present disclosure are hereinafter summarized to provide a basic understanding. This summary is not an exhaustive overview of the disclosure and is neither intended to identify certain elements of the disclosure, nor to delineate the scope thereof. Rather, the primary purpose of this summary is to present some concepts of the disclosure in a simplified form prior to the more detailed description that is presented hereinafter.

In one or more aspects, the present disclosure provides a photovoltaic module comprising; a first polycarbonate layer having a first major surface and a second major surface; a first thermoplastic polyurethane (TPU) layer having a first major surface and a second major surface, wherein the first major surface of the first TPU layer is in contact with the second major surface of the first polycarbonate layer; a first encapsulation layer having a first major surface and a second major surface, wherein the first major surface of the first encapsulation layer is in contact with the second major surface of the first TPU layer; and a solar cell having a first major surface and a second major surface, wherein the first major surface of the solar cell is in contact with the second major surface of the first encapsulation layer.

In another aspect, the present disclosure provides a method of building a photovoltaic module comprising; positioning a first encapsulation layer having a first major surface and a second major surface and a solar cell having a first major surface and a second major surface such that the first major surface of the solar cell is in contact with the second major surface of the first encapsulation layer; positioning a first thermoplastic polyurethane (TPU) layer having a first major surface and a second major surface, such that the first major surface of the first encapsulation layer is in contact with the second major surface of the first TPU layer; positioning a first polycarbonate layer having a first major surface and a second major surface such that the first major surface of the first TPU layer is in contact with the second major surface of the first polycarbonate layer; and laminating the first polycarbonate layer, the first TPU layer, the first encapsulation layer, and the solar cell.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

FIG. 1A-1B is a diagram of a non-limiting system of the present disclosure assembling a single facial (FIG. 1A) or bi-facial (FIG. 1B) photovoltaic module.

FIG. 2 is a graph for transmittance of UV, visible light, and infrared (IR) light through glass, EVA, and polycarbonate (Lexan).

FIG. 3 is a graph illustrating the peel resistance of thermoplastic polyurethane (TPU) adhered to polycarbonate under two different lamination conditions, as compared to EVA adhered to glass.

FIG. 4 depicts a non-limiting example of TPU-polycarbonate photovoltaic module.

FIG. 5 is a graph illustrating the electrical performance degradation of polycarbonate photovoltaic modules adhered with TPU during a damp heat (DH) test.

FIG. 6A-6B depicts a non-limiting example of a polycarbonate photovoltaic module tested in humidity freezing (HF) and an image of the module by electroluminescence (EL) imaging.

FIG. 7A-7B depict a schematic and an image of a polycarbonate sample under lap shear testing of mechanical adhesion.

FIG. 8 is a graph illustrating lap shear testing represented by shear stress (mPa) and displacement of laminated samples.

### DETAILED DESCRIPTION

As used herein, the term “photovoltaic module,” “PV module,” “solar panels,” and grammatical variants thereof, refers generally to an apparatus or enclosure that generates electrical energy by conversion of light energy it absorbs. The PV module may be composed of an array of solar cells connected by any manner as chains, covered by at least one front plate and back plate, and sealed together by a sealant such as an encapsulant. Additional electrical connections such as a junction box or wire leads may be attached to the back of the PV module. The PV module may or may not be a frameless apparatus. The PV module may or may not have a back plate.

As used herein, the term “encapsulant,” “solar encapsulant,” and grammatical variants thereof, refers generally to a copolymer resin for the complete envelopment of a solar cell to protect from jostling and shocks, as well as protection from oxidation by gases such as oxygen. The encapsulant may allow for solar transmission, have excellent adhesion properties with the plates and solar cell, have superior dielectric properties, and resistant to water and vapor.

As used herein, the term “solar cell,” and grammatical variants thereof, refers generally to a device capable of converting photons (solar energy) absorbed through an antireflection layer into an electrical current through the photovoltaic effect. Below the antireflection layer of the solar cell is a top and back junction layer sandwiching an absorber layer core, along with two additional electrical contact layers to carry the electric current through an electric circuit to induce an electric field. Solar cells typically comprise a semiconductor material that absorbs visible light and other radiation. The semiconductor material may include silicon, gallium arsenide, indium phosphide, and copper indium selenide. The solar cell may refer to one or more solar cells arranged in a variety of configurations such as arrays.

Solar panels, or PV modules, require proper sealing and protection of solar cells using transparent materials. Current PV modules are assembled with fragile glass plating that suffer logistics challenges with complications in transportation and installation of assemblies. Also, glass has a minimum density of 2.2 g/cm³, which renders PV modules containing glass plating relatively heavy and adds difficulty to transportation and installation. Though PV modules substituting the glass plating with a polymer material would address the logistical hurdles, current encapsulants adhere poorly to the polymer materials.

To address the aforementioned shortcomings of current PV assemblies, the present disclosure provides a lightweight PV assembly utilizing a durable module sealed for enhanced environmental stability. The PV module would be assembled with a durable transparent thermoplastic polymer plate adhered to a solar cell by multiple layers of encapsulant sealants between the solar cell and thermoplastic plating.

Accordingly, methods in the present disclosure may include a method of building a photovoltaic module comprising; providing a photovoltaic module comprising a transparent thermoplastic polymer plate, a multilayer sealant, and a solar cell; and compressing the photovoltaic module.

Also described herein is a PV module composition comprising: a transparent thermoplastic polymer sheet coated in a U.V. stabilizing additive and an anti-abrasion material; a TPU film adhesive; an encapsulant copolymer film; and a solar cell.

In some embodiments, the present disclosure relates to a photovoltaic module comprising a first polycarbonate layer having a first major surface and a second major surface; a first thermoplastic polyurethane (TPU) layer having a first major surface and a second major surface, wherein the first major surface of the first TPU layer is in contact with the second major surface of the first polycarbonate layer; a first encapsulation layer having a first major surface and a second major surface, wherein the first major surface of the first encapsulation layer is in contact with the second major surface of the first TPU layer; and a solar cell having a first major surface and a second major surface, wherein the first major surface of the solar cell is in contact with the second major surface of the first encapsulation layer.

A layer, sheet, plate, or film is a three-dimensional structure in which two of its dimensions, which will generally be referred to as height and width, are much larger than its third dimension, which will generally be referred to as thickness. A surface having height and width may be referred to as a major surface, of which the layer etc. will have two on opposed faces. The surfaces between the major surfaces, in which one dimension is the thickness of the layer etc., may each be referred to as an edge.

The photovoltaic module described above may be considered a monofacial or single facial PV module. In some embodiments, a photovoltaic module of the present disclosure may further comprise a second polycarbonate layer having a first major surface and a second major surface; a second thermoplastic polyurethane (TPU) layer having a first major surface and a second major surface, wherein the first major surface of the second TPU layer is in contact with the second major surface of the second polycarbonate layer; and a second encapsulation layer having a first major surface and a second major surface, wherein the first major surface of the second encapsulation layer is in contact with the second major surface of the second TPU layer, and the second major surface of the second encapsulation layer is in contact with the second major surface of the solar cell. A photovoltaic module of these embodiments may be considered a bifacial PV module.

Though not to be bound by theory, bifacial PV modules may capture both direct (incident) sunlight and indirect (ground reflected and atmospherically diffused) sunlight, thereby increasing overall energy production.

Methods of the present disclosure may include a method of building a photovoltaic module comprising positioning a first encapsulation layer having a first major surface and a second major surface and a solar cell having a first major surface and a second major surface such that the first major surface of the solar cell is in contact with the second major surface of the first encapsulation layer; positioning a first thermoplastic polyurethane (TPU) layer having a first major surface and a second major surface, such that the first major surface of the first encapsulation layer is in contact with the second major surface of the first TPU layer; positioning a first polycarbonate layer having a first major surface and a second major surface such that the first major surface of the first TPU layer is in contact with the second major surface of the first polycarbonate layer; and laminating the first polycarbonate layer, the first TPU layer, the first encapsulation layer, and the solar cell.

A PV module may be assembled within a frame, rack, or fixed mount for the purpose of sealing or fastening the module. In various embodiments, the PV module is assembled and laminated within an aluminum extrusion frame. One skilled in the art may assemble the PV module with a frameless configuration.

The PV module may be constructed with at least a single transparent or semi-transparent front plate and/or back plate, such as a first polycarbonate layer and/or a second polycarbonate layer, where the plate must be transparent enough to allow transmittance of visible light. In various embodiments, the PV module plate may have a thickness of about 2 mm to about 3 mm. In some embodiments, the PV module may be assembled with a front plate and a back plate in a bifacial configuration.

The PV module front plate, e.g., the first polycarbonate layer, may be transparent or semi-transparent thermoplastic that has impact strength and dimensional stability. In various embodiments, the thermoplastic plate material may be a multipolymer mixture or material selected from the group consisting of polycarbonate (PC), acrylic, polyethylene terephthalate (PET), ethylene tetrafluoroethylene (ETFE), or any combination thereof. In a non-limiting example, the front plate of the PV module is a PC material. In a non-limiting example, the PC front plate has a thickness of about 2 mm to about 3 mm.

In some embodiments, the thermoplastic plate comprises a light-weight PC material with a high strength combined with its light weight. PC has a density of about 1.2 g/cm³, which renders sheets or layers thereof much lighter than a glass sheet of identical surface area and thickness. The impact resistance (kJ/m²) of PC may be significantly higher in comparison to the glass front plate standard of a PV module (Table 1).

TABLE 1

| Material | Impact Resistance (kJ/m²) |
|---|---|
| Glass | 1 |
| Polycarbonate | 35 |

The PV module front plate and/or back plate may be applied with coatings and additives to confer resistance against environmental factors such as radiation, weather wear-and-tear, and the like. Coating and additives may be any chemical compounds or agents known to one skilled in the art and may be applied in any form or fashion.

UV resistant additives, also known as UV absorbers or UV stabilizers, are materials that absorb high energy UV light, which may protect other materials from UV radiation. In one or more embodiments, the front plate and/or back plate of the PV module may comprise a UV stabilizer. For example, the UV stabilizer may be selected from the group consisting of benzotriazoles, benzophenones, organic nickel compounds, hydroxyphenyltriazines, and combinations thereof.

Anti-abrasion or anti-scratch agents are materials that prevent physical damage by enhancing resistance of a surface to friction and tear, as well as preventing degradation. In some embodiments, PV modules may further comprise anti-abrasion layers applied to the front and/or back plate of the PV module. For example, the anti-abrasion layer may comprise a material selected from the group consisting of fluoropolymers (e.g. Xylan® (PPG Industries Ohio, Inc., Pittsburgh, PA), epoxy, polyphenylene sulfide (PPS), ethylene tetrafluoroethylene (ETFE), ethylene-chlorotrifluoroethylene (ECTFE), polyvinylidene (di)fluoride (PVDF), or combinations thereof.

The PV module may include an adhesive agent to properly seal the assembly and protect the solar cell from deterioration from harsh climate conditions, as well as regulate the absorption of UV rays and deter oxidation. The adhesive agent, or encapsulant, may be a polymer or co-polymer with high optical transmittance applied during the lamination of a PV modules assembly. In various embodiments, the encapsulant may be selected from the group consisting of ethylene vinyl acetate (EVA) copolymer, polyolefin elastomer (POE), polyvinyl butyral (PVB), silicone, thermoplastic silicone elastomer (TPSE), thermoplastic polyolefin elastomer (TPO), or ionomers, thermoplastic polyurethane (TPU), and combinations thereof.

The TPU film encapsulant may have superior adhesion to thermoplastic plates as compared to traditional encapsulants in PV module assemblies, as well as superior module performance due to its high transparency. In one or more embodiments, the PV module comprises at least a single TPU layer adhering the front plate and the solar cell. However, TPU may absorb an excess amount of humidity and thereof may degrade under humid conditions and high temperatures.

To compensate for these potential TPU vulnerabilities under humid conditions, the addition of at least one other encapsulant layer after the TPU film (e.g., between the TPU film and the solar cell) in a PV module may be introduced. The interface of two different encapsulant layers chemistries may improve the PV module resistance to humidity ingress and provide optimal adhesion to the PV module plating and solar cell.

In one or embodiments, the PV module may be sealed with multiple layers of encapsulants comprising a TPU top layer bound to the front plate, followed by at least one other encapsulant layer between the TPU layer and the solar cell, where the other encapsulant layer may be selected from the group consisting of EVA, POE, TPO, TPSE, ionomers, PVB, and combinations thereof. In some embodiments, the multiple encapsulants of TPU layer and a non-TPU encapsulant sealing the PV module may be extruded as a composite single sheet.

Multiple layers of encapsulants may be combined in a plurality of ratios. In some embodiments, the combination ratio of the multiple layer of encapsulant may be 1:1 by density (grams per cubic centimeter (g/cc)) of a TPU encapsulant layer and another non-TPU encapsulant layer, where the non-TPU encapsulant layer may be selected from the group consisting of, but not limited to, EVA, TPO, Ionomer, PVB, or any combination thereof. In some embodiments, the multiple layers of encapsulants may be at a density ratio ranging from about 1:5 to about 5:1, including all values and subranges therebetween.

In various embodiments, TPU layers and encapsulant layers may range in thickness from about 0.2 mm to about 1.2 mm. In a non-limiting example, TPU layers may each be 0.65 mm thick. In another non-limiting example, encapsulant layers may each be 0.4 mm thick. In a non-limiting example, the multilayer encapsulant comprises a TPU encapsulant layer that is 0.65 mm thick, and the subsequent encapsulant layer (EVA, TPO, Ionomer, or PVB) is 0.4 mm thick.

The solar cell within the PV module may be enveloped by an encapsulant layer, and may have a configuration selected from, but not limited to, a film-based cell, a wafer-based cell, or any combination thereof. The solar cell may be adhered to the plating of the PV module by an encapsulant or multiple layers of encapsulants. The solar cell may be an individual cell, a linkage of multiple solar cells, and/or a stacking of multiple solar cells. In one or more embodiments, the solar cell is a silicon selected from the group consisting of monocrystalline silicon, polycrystalline silicon, thin film, or a combination thereof. In a non-limiting example, the solar cell may be comprised of crystalline silicon.

In some embodiments, the solar cell may be made up of a non-silicon material, including but not limited to, perovskite cell, an organic solar cell, a dye-sensitized solar cell, quantum dots, or a combination thereof.

The solar cell generates electricity by conversion of light and radiation. The range of wavelengths that the PV module can convert may range from about 300 nm to about 1800 nm, including all wavelength values and subranges therebetween (e.g. 300 nm, 400 nm, 500 nm, 700 nm, 1000 nm, 1100 nm, 1200 nm, 1500 nm, or 1800 nm). In various embodiments, the PV module may convert solar energy at a wavelength of 300 nm to 1500 nm, 400 nm to 1500 nm, 500 nm to 1500 nm, 700 nm to 1500 nm, 1000 nm to 1500 nm, 1100 nm to 1500 nm, 1200 nm to 1500 nm, 300 nm to 1200 nm, 300 nm to 1100 nm, 300 nm to 1000 nm, 300 to 700 nm, 300 nm to 500 nm, or 300 nm to 400 nm.

In some embodiments, the PV module meets the IEC 61215-2 International Standard for long-term operations of flat plate module solar panels in open-air climates.

The PV module may be fabricated and sealed by a process of lamination. In various embodiments, the PV module may be laminated by a plurality of methods familiar to one skilled in the art. The lamination of the PV module seals the solar cell between layers of protective materials to prevent environmental damage and ingress of moisture. In some embodiments, the PV module is assembled and laminated by a lamination machine applying heat and pressure to the PV module within a vacuum chamber, ensuring proper bondage between all PV module layers. The lamination machine method may remove air bubbles and impurities. In one or embodiments, the PV module is compressed by a lamination technique selected from the group consisting of, but not limited to, encapsulant lamination, flatbed lamination, hot melt lamination, roll-to-roll lamination or any combination thereof.

In some embodiments, the PV module may be laminated within a heated chamber to which vacuum may be applied. The chamber may be under a membrane pressure range of about 400 mbar to about 1500 mbar. The working temperature within the laminator may range from about 45° C. to about 150° C. Vacuum may be applied for 5 minutes to 2 hours to remove bubbles from the TPU layer(s) and encapsulant layer(s). In a non-limiting example, the PV module may be laminated at a temperature of 130° C. under a pressure of 1400 mbar, followed by 30 minutes of vacuum, for a total lamination process lasting about 36 minutes.

In various embodiments, the PV module may be fabricated by encapsulant lamination, wherein the PV module solar cells are enveloped by a single (or plural) sheet of encapsulant film such as EVA film. The encapsulant film is then heated and pressed onto the solar cells.

In some embodiments, the PV module may be fabricated by flatbed lamination, wherein the solar cell is placed between two sheets of tempered glass or an encapsulant film such as EVA, then bonded by heat and pressure. The solar cells may comprise crystalline silicon solar panels.

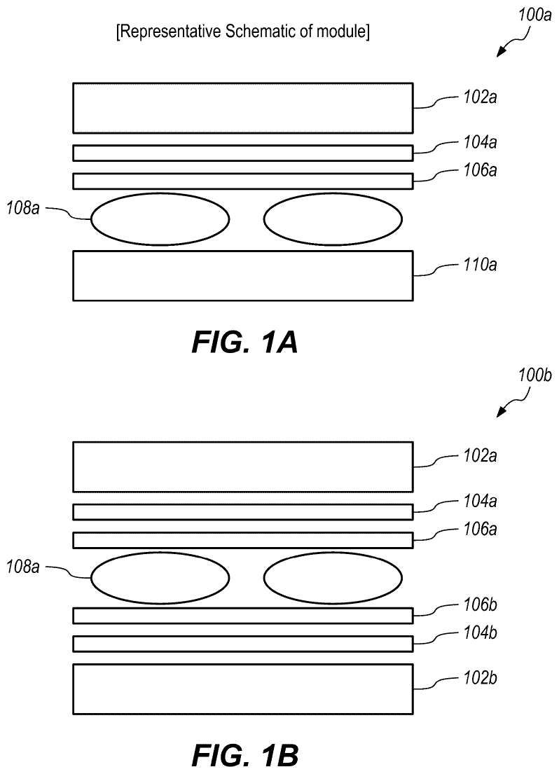

FIG. 1A is a diagram of a non-limiting system and method of the present disclosure assembling a PV module for generating an electrical current from converted absorbed sunlight. The first major surface of the depicted components is toward the top of the view and the second major surface is toward the bottom.

As shown, system and method 100a includes a PC top plate (first PC layer) 102a at the face of the PV module, adhered to the front of the solar cell 108a by multiple layers of encapsulants. The first encapsulant layer 104a attached to the front plate comprises TPU. The second layer of encapsulant between the TPU layer 104a and the solar cell 108a is an encapsulant layer 106a selected from the group consisting of ethylene vinyl acetate (EVA) copolymer, polyolefin elastomer (POE), polyvinyl butyral (PVB), silicone, thermoplastic silicone elastomer (TPSE), thermoplastic polyolefin elastomer (TPO), ionomers, and combinations thereof. At the back of the solar cell 108a is a supportive plate 110a. The supportive plate 110a may comprise aluminum, steel, other metals, plastics, PET polymer, opaque fluoropolymer, or other materials. The supportive plate 110a may include a reflective material that may reflect photons to the solar cell 108a, which may increase energy production.

FIG. 1B is a diagram of a non-limiting system and method of the present disclosure assembling a bifacial PV module for generating an electrical current from converted absorbed sunlight. Components with reference numerals ending in “a” are as described with reference to FIG. 1A. Components with reference numerals ending in “b” have a first major surface toward the bottom of the view and a second major surface toward the top of the view.

As shown, system and method 100b includes a PC top plate 102a at the face of the PV module, adhered to the front of the solar cell 108a by multiple layers of encapsulants 104a-106a. The layer 104a attached to the front plate comprises TPU, e.g. is a first TPU layer. The first encapsulant layer between the TPU layer 104a and the solar cell 108a is a first encapsulant layer 106a selected from the group consisting of ethylene vinyl acetate (EVA) copolymer, polyolefin elastomer (POE), polyvinyl butyral (PVB), silicone, thermoplastic silicone elastomer (TPSE), thermoplastic polyolefin elastomer (TPO), ionomers, or any combination thereof. At the back of the solar cell 108a, a second encapsulant layer 106b of similar composition to first encapsulation layer 106a is layered. Following this layer, a second TPU layer 104b is layered between the second encapsulant layer 106b and a PC back plate (second PC layer) 102b.

While various embodiments have been shown and described herein, modifications may be made by one skilled in the art without departing from the scope of the present disclosure. The embodiments described here are exemplary only, and are not intended to be limiting. Many variations, combinations, and modifications of the embodiments disclosed herein are possible and are within the scope of the disclosure. Accordingly, the scope of protection is not limited by the description set out above, but is defined by the claims which follow, that scope including all equivalents of the subject matter of the claims.

### EXAMPLE EMBODIMENTS (CLAIMS BANK)

Embodiments disclosed herein include:

Embodiment A: a photovoltaic module, comprising: a first polycarbonate layer having a first major surface and a second major surface; a first thermoplastic polyurethane (TPU) layer having a first major surface and a second major surface, wherein the first major surface of the first TPU layer is in contact with the second major surface of the first polycarbonate layer; a first encapsulation layer having a first major surface and a second major surface, wherein the first major surface of the first encapsulation layer is in contact with the second major surface of the first TPU layer; and a solar cell having a first major surface and a second major surface, wherein the first major surface of the solar cell is in contact with the second major surface of the first encapsulation layer.

Embodiment B: a method of building a photovoltaic module comprising: positioning a first encapsulation layer having a first major surface and a second major surface and a solar cell having a first major surface and a second major surface such that the first major surface of the solar cell is in contact with the second major surface of the first encapsulation layer; positioning a first thermoplastic polyurethane (TPU) layer having a first major surface and a second major surface, such that the first major surface of the first encapsulation layer is in contact with the second major surface of the first TPU layer; positioning a first polycarbonate layer having a first major surface and a second major surface such that the first major surface of the first TPU layer is in contact with the second major surface of the first polycarbonate layer; and laminating the first polycarbonate layer, the first TPU layer, the first encapsulation layer, and the solar cell.

By way of non-limiting example, exemplary combinations applicable to Embodiments A through C include:
Element 1: wherein the first polycarbonate layer comprises a UV stabilizer.
Element 2: wherein the UV stabilizer is selected from the group consisting of benzotriazoles, benzophenones, organic nickel compounds, and combinations thereof.
Element 3: further comprising a first anti-abrasion layer having a first major surface and a second major surface, wherein the second major surface of the first anti-abrasion layer is in contact with the first major surface of the first polycarbonate layer.
Element 4: wherein the first anti-abrasion layer comprises a material selected from the group consisting of fluoropolymers, epoxy, polyphenylene sulfide (PPS), ethylene tetrafluoroethylene (ETFE), ethylene-chlorotrifluoroethylene (ECTFE), polyvinylidene (di)fluoride (PVDF), and combinations thereof.
Element 5: wherein the first TPU layer has a thickness between 0.2 mm and 1.2 mm.
Element 6: wherein the first encapsulation layer comprises a material selected from the group consisting of ethylene vinyl acetate (EVA) copolymer, polyolefin elastomer (POE), polyvinyl butyral (PVB), silicone, thermoplastic silicone elastomer (TPSE), thermoplastic polyolefin elastomer (TPO), ionomers, and combinations thereof.
Element 7: wherein the first encapsulation layer has a thickness between 0.2 mm and 1.2 mm.
Element 8: further comprising a frame in contact with one or more edges of the first polycarbonate layer, the first TPU layer, the first encapsulation layer, and the solar cell.
Element 9: wherein the solar cell converts energy having a wavelength from about 300 nm to about 1800 nm to electricity.
Element 10: wherein the first polycarbonate layer has an average transmittance of light from 400 nm to 1100 nm of at least 85% at a layer thickness of 3 mm or less.
Element 11: further comprising: a second polycarbonate layer having a first major surface and a second major surface; a second thermoplastic polyurethane (TPU) layer having a first major surface and a second major surface, wherein the first major surface of the second TPU layer is in contact with the second major surface of the second polycarbonate layer; and a second encapsulation layer having a first major surface and a second major surface, wherein the first major surface of the second encapsulation layer is in contact with the second major surface of the second TPU layer, and the second major surface of the second encapsulation layer is in contact with the second major surface of the solar cell.
Element 12: wherein the second polycarbonate layer comprises a UV stabilizer.
Element 13: wherein the UV stabilizer of the second polycarbonate layer is selected from the group consisting of benzotriazoles, benzophenones, organic nickel compounds, and combinations thereof.
Element 14: further comprising a second anti-abrasion layer having a first major surface and a second major surface, wherein the second major surface of the second anti-abrasion layer is in contact with the first major surface of the second polycarbonate layer.
Element 15: wherein the second anti-abrasion layer comprises a material selected from the group consisting of fluoropolymers, epoxy, polyphenylene sulfide (PPS), ethylene tetrafluoroethylene (ETFE), ethylene-chlorotrifluoroethylene (ECTFE), polyvinylidene (di)fluoride (PVDF), and combinations thereof.
Element 16: wherein the second TPU layer has a thickness between 0.2 mm and 1.2 mm.
Element 17: wherein the second encapsulation layer comprises a material selected from the group consisting of ethylene vinyl acetate (EVA) copolymer, polyolefin elastomer (POE), polyvinyl butyral (PVB), silicone, thermoplastic silicone elastomer (TPSE), thermoplastic polyolefin elastomer (TPO), ionomers, and combinations thereof.
Element 18: wherein the second encapsulation layer has a thickness between 0.2 mm and 1.2 mm.
Element 19: further comprising a frame in contact with one or more edges of the second polycarbonate layer, the second TPU layer, the second encapsulation layer, and the solar cell.
Element 20: wherein the first TPU layer and the first encapsulant layer are coextruded.
Element 21: wherein the first encapsulation layer comprises a material selected from the group consisting of ethylene vinyl acetate (EVA) copolymer, polyolefin elastomer (POE), polyvinyl butyral (PVB), silicone, thermoplastic silicone elastomer (TPSE), thermoplastic polyolefin elastomer (TPO), ionomers, and combinations thereof.
Element 22: further comprising positioning a first anti-abrasion layer having a first major surface and a second major surface such that the second major surface of the first anti-abrasion layer is in contact with the first major surface of the first polycarbonate layer.
Element 23: wherein the first anti-abrasion layer comprises a material selected from the group consisting of fluoropolymers, epoxy, polyphenylene sulfide (PPS), ethylene tetrafluoroethylene (ETFE), ethylene-chlorotrifluoroethylene (ECTFE), polyvinylidene (di)fluoride (PVDF), and combinations thereof.
Element 24: further comprising, prior to the laminating: positioning a second encapsulation layer having a first major surface and a second major surface such that the second major surface of the solar cell is in contact with the second major surface of the second encapsulation layer; positioning a second thermoplastic polyurethane (TPU) layer having a first major surface and a second major surface, such that the first major surface of the second encapsulation layer is in contact with the second major surface of the second TPU layer; and positioning a second polycarbonate layer having a first major surface and a second major surface such that the first major surface of the second TPU layer is in contact with the second major surface of the second polycarbonate layer.
Element 26: wherein the second TPU layer and the second encapsulant layer are coextruded.
Element 27: wherein the second encapsulation layer comprises a material selected from the group consisting of ethylene vinyl acetate (EVA) copolymer, polyolefin elastomer (POE), polyvinyl butyral (PVB), silicone, thermoplastic silicone elastomer (TPSE), thermoplastic polyolefin elastomer (TPO), ionomers, and combinations thereof.
Element 28: further comprising, prior to the laminating, positioning a second anti-abrasion layer having a first major surface and a second major surface such that the second major surface of the second anti-abrasion layer is in contact with the first major surface of the second polycarbonate layer.
Element 29: wherein the second anti-abrasion layer comprises a material selected from the group consisting of fluoropolymers, epoxy, polyphenylene sulfide (PPS), ethylene tetrafluoroethylene (ETFE), ethylene-chlorotrifluoroethylene (ECTFE), polyvinylidene (di)fluoride (PVDF), and combinations thereof.
Element 30: wherein the lamination comprises 30 minutes of vacuum.
Element 31: wherein the lamination is performed at a temperature of about 130° C.
Element 32: wherein the lamination is performed at a pressure of about 1400 mbar.
Element 33: wherein the lamination comprises encapsulant lamination, flatbed lamination, hot melt lamination, or any combination thereof.
Element 34: further comprising framing the photovoltaic module.

To facilitate a better understanding of the embodiments described herein, the following examples of various representative embodiments are given. In no way should the following examples be read to limit, or to define, the scope of the present disclosure.

### EXAMPLES

A photovoltaic (PV) module was assessed for radiation transmittance efficiency through the front plate, and module durability and environmental stability. Encapsulants that seal the PV modules were tested for adhesion proficiency within the PV module both individually and in combination with other encapsulants as a multi-layer sealant.

### Method

The material of the front plate tested herein is a solar glass or a polycarbonate plate. The polycarbonate plate is a Lexan SLX2471T-E17 provided by Sabic Lexan.

Solar panel efficiency was measured as follows:

$$Power out / Power in = ( Max . Power / PV area ) / ( Sunlight Intensity / {m}^{2} )$$

$$Sunlight Intensity = 100 W / {m}^{2}$$

$$Standard Test Condition ( STC ) = 1000 W / {m}^{2} at 25 deg C and 1.5 air mass ( AM ) .$$

The average transmittance (%) of ultraviolet (UV), visible light, and infrared light (IR) (by wavelength (nm)) of solar glass and PC was mapped against Spectral Solar Irradiance (sunlight intensity) (W/m²/nm).

Encapsulant adhesion efficiency to a polycarbonate (PC) plate was assessed by peel force (N/cm) under a lamination pressure ranging between 1000 mbar to 1400 mbar.

The degradation of electrical performance of PV modules under damp heat (DH) conditions (85° C., 85% relative humidity) was measured by loss from initial values of maximum power (Pmpp), short circuit current (Isc), open circuit voltage (Voc), and fill factor (FF).

Environmental stability of fully assembled PV modules fabricated with PC plate(s) and TPU encapsulant were assessed by accelerated life testing. The range of PV module thermal stability was tested by DH accelerated climate testing. The range of PV module extreme cold and heat stability was tested by humidity freeze (HF), represented by 10 temperature cycles within a temperature range of −40° C. to 85° C. at 85% RH.

The PV module was assembled by a customized lamination process. The process took about 36 minutes, including a temperature of 130° C., a pressure of 1400 mbar, and a 30 minute vacuum step. An exemplary PV module assembled by the process is depicted in FIG. 4.

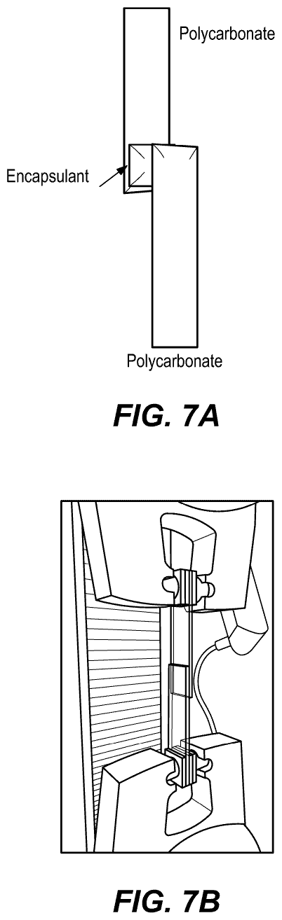

The mechanical adhesion of additional encapsulant layers in the interface between the solar cell and TPU encapsulant of the PV module was assessed by lab shear technique with a sample configuration schematically depicted in FIG. 7A, with a sample under test shown in FIG. 7B. A variety of combinations of TPU encapsulant with other commercial encapsulants (PVB and Ionomer) paradigms were graphed as shear stress (MPa) versus displacement (mm), with glass-EVA and glass-PVB standards used as a reference.

Mini PV modules fabricated with multilayer encapsulants (TPU/PVB, TPU/POE, TPU/EVA) underwent preliminary tests by accelerated life testing DH over the span of five weeks.

### Results

### Transmittance of Polycarbonate

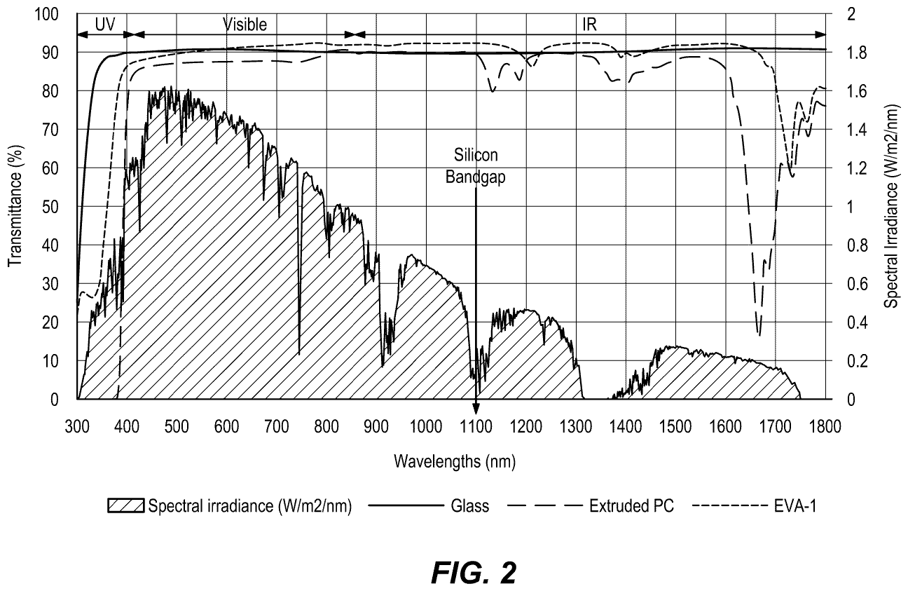

Preliminary tests were conducted to compare the average transmittance of UV, visible, and infrared light (IR) between solar glass and transparent PC sheet samples, testing within a wavelength range of 300 nm to 1800 nm (FIG. 2). Results showed PC and glass transmittance were comparable. Additionally, EVA absorbed much of the light in the UV range of 300 nm-400 nm.

In Table 2, the percentage of average transmittance within a wavelength spectra of 400 nm to 1100 nm was compared between a solar glass and two PC sheets. The 400 nm-1100 nm wavelength range is what is most efficiently converted by silicon solar panels.

TABLE 2

| Sample type | Average transmittance (400-1100 nm) |
|---|---|
| Solar glass | 89.94% |
| Sabic Lexan 2 mm | 88.08% |
| Sabic Lexan 3 mm | 87.13% |

Electrical and Gross Structural Properties of PV Modules Comprising PC Front Plate with TPU as Sole Encapsulant Layer

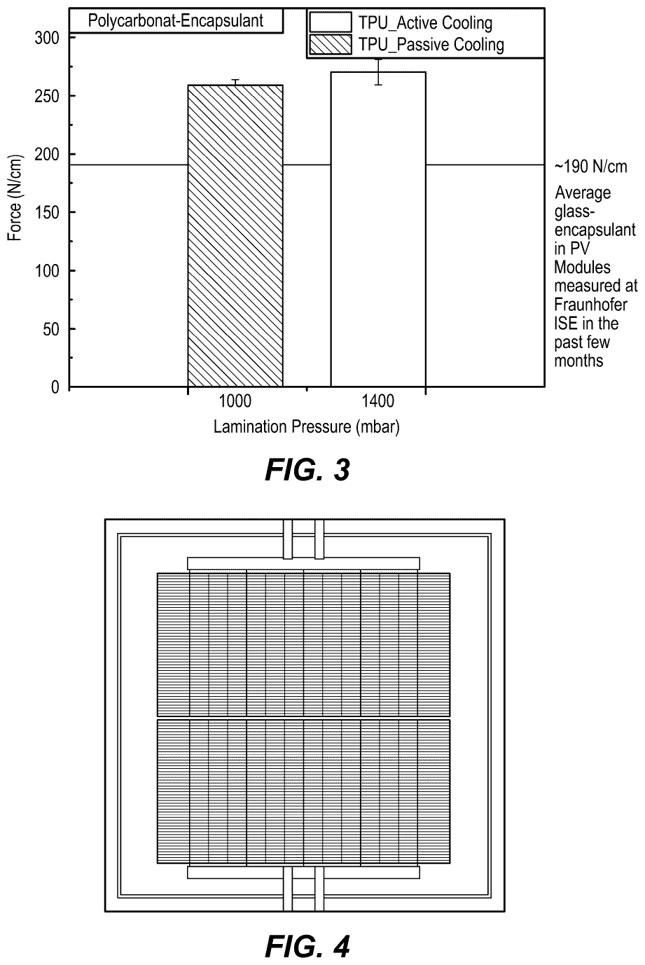

Prototypes of PV modules were fabricated and assessed for adhesion efficiency of their encapsulant polymers. TPU adhered to PC with a peel force of about 250 N/cm to 275 N/cm, which was greater than the average peel force for glass-EVA (about 190 N/cm) (FIG. 3).

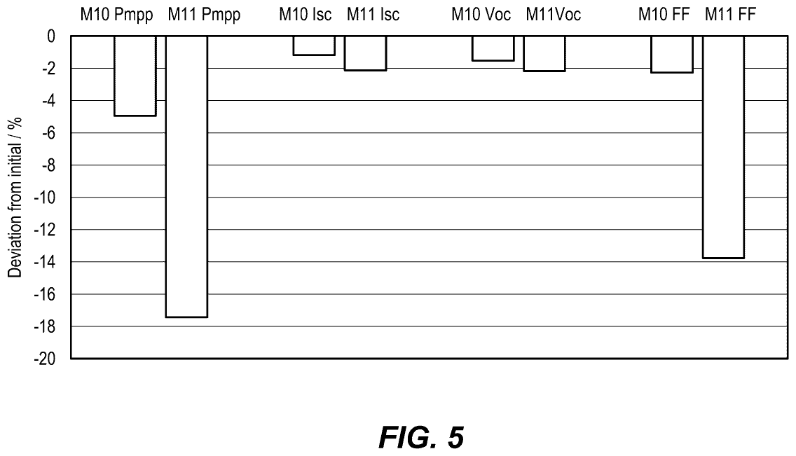

The TPU encapsulant was found to absorb humidity. Under DH accelerated climate testing conditions (85° C. and 85% RH), the electrical performance (Pmpp) of two PV modules comprising TPU as the sole encapsulant layer were degraded beyond the 5% limit as defined by IEC 61215 standard, and the FF performance of one of the samples was also degraded beyond the 5% limit (FIG. 5). PV modules M10 and M11 were comprised of passivated emitter and rear contact (PERC) solar cells. PV module M11 was configured for bifacial operation.

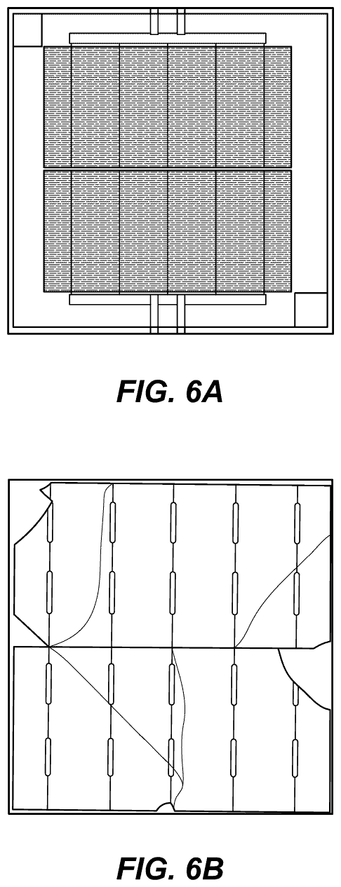

Similarly, in another accelerated life testing under extreme cold with HF testing, PV modules demonstrated excessive power loss (>10%, results not shown), as well as excessive bubble formation (FIG. 6A). Additionally, electroluminescence (EL) imaging revealed extensive cracks in PV modules comprising PC and a single TPU encapsulant layer under the HF testing, indicative of PV module instability (FIG. 6B).

Structural Properties of PV Modules Comprising PC Front Plate with TPU and an Additional Encapsulant Layer

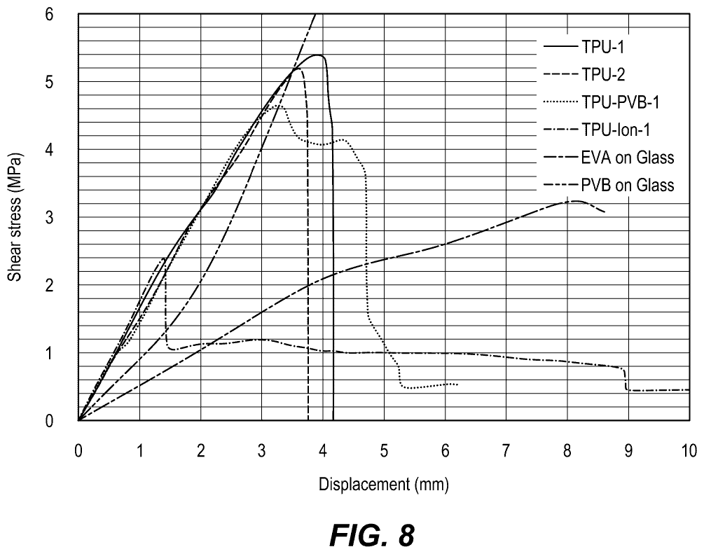

Additional layers of encapsulant with varying chemistries were added as an interface between the TPU layer and the solar cell. Combinations of encapsulants included TPU-PVB and TPU-Ionomer with PC front plates. TPU-PC, EVA-solar glass, and PVB-solar glass were used as controls. FIG. 8 shows results of lab shear testing. TPU-PC had high peak stress (>5 MPa), but broke at a low displacement of 4 mm. The control EVA-solar glass showed a lower peak stress (3 Mpa) but endured a higher displacement (>8 mm). The control PVB-solar glass demonstrated the highest peak stress. The two combination polymers (TPU-PVB and TPU-Ionomer, both with PC front plates) showed lower peak stress than the TPU-PC control, but also endured a significantly higher displacement. The higher displacement suggests bonds between different layers would remain more stable under harsh environmental conditions, such as those simulated by the DH and HF tests. This may include a higher resistance to moisture in high humidity environments.

Electrical Properties of PV Modules Comprising PC Front Plate with TPU and an Additional Encapsulant Layer after Extended Damp Heat Conditions

PV modules with a multilayer encapsulant combination between the PC front plate and solar cell were fabricated and tested under DH conditions for a duration of five weeks. A control module comprising TPU as the sole encapsulant layer was also tested. The components of the encapsulant layer(s) of the PV modules are set forth in Table 3, along with power losses after five weeks of DH testing. Power loss was the lowest for PV modules with TPU/PVB and TPU/POE multilayer encapsulants (Table 3), with both showing a power loss within the acceptable range of the IEC 61215 standard (less than 5%). PV modules comprising a TPU layer as the sole encapsulant layer displayed the greatest loss in power, followed by modules comprising a TPA/EVA multilayer encapsulant.

TABLE 3

| Encapsulant type | Power loss after DH test | Comments |
|---|---|---|
| TPU | 35.51% | Several small bubble |
| | | formations, cell cracks |
| TPU/PVB | 1.26% | Minor performance loss, |
| | | bubble formation |
| TPU/EVA | 5.98% | Large bubble formation |
| TPU/POE | 1.96% | Minor performance loss, |
| | | bubble formation |

The terminology used herein is for the purpose of describing particular embodiments only and is not intended to be limiting of the invention. As used herein, for example, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof.

Terms of orientation used herein are merely for purposes of convention and referencing and are not to be construed as limiting. However, it is recognized these terms could be used with reference to an operator or user. Accordingly, no limitations are implied or to be inferred. In addition, the use of ordinal numbers (e.g., first, second, third, etc.) is for distinction and not counting. For example, the use of “third” does not imply there must be a corresponding “first” or “second.” Also, if used herein, the terms “coupled” or “coupled to” or “connected” or “connected to” or “attached” or “attached to” may indicate establishing either a direct or indirect connection, and is not limited to either unless expressly referenced as such.

While the disclosure has described several exemplary embodiments, it will be understood by those skilled in the art that various changes can be made, and equivalents can be substituted for elements thereof, without departing from the spirit and scope of the invention. In addition, many modifications will be appreciated by those skilled in the art to adapt a particular instrument, situation, or material to embodiments of the disclosure without departing from the essential scope thereof. Therefore, it is intended that the invention not be limited to the particular embodiments disclosed, or to the best mode contemplated for carrying out this invention, but that the invention will include all embodiments falling within the scope of the appended claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

1. A photovoltaic module, comprising:
a first polycarbonate layer having a first major surface and a second major surface;
a first thermoplastic polyurethane (TPU) layer having a first major surface and a second major surface, wherein the first major surface of the first TPU layer is in contact with the second major surface of the first polycarbonate layer;
a first encapsulation layer having a first major surface and a second major surface, wherein the first encapsulation layer comprises silicone, thermoplastic silicone elastomer (TPSE), ionomers, and combinations thereof, wherein the first major surface of the first encapsulation layer is in contact with the second major surface of the first TPU layer; and
a solar cell having a first major surface and a second major surface, wherein the first major surface of the solar cell is in contact with the second major surface of the first encapsulation layer.

2. The photovoltaic module of claim 1, wherein the first polycarbonate layer comprises a UV stabilizer.

3. The photovoltaic module of claim 2, wherein the UV stabilizer is selected from the group consisting of benzotriazoles, benzophenones, organic nickel compounds, and combinations thereof.

4. The photovoltaic module of claim 1, further comprising a first anti-abrasion layer having a first major surface and a second major surface, wherein the second major surface of the first anti-abrasion layer is in contact with the first major surface of the first polycarbonate layer.

5. The photovoltaic module of claim 4, wherein the first anti-abrasion layer comprises a material selected from the group consisting of fluoropolymers, epoxy, polyphenylene sulfide (PPS), ethylene tetrafluoroethylene (ETFE), ethylene-chlorotrifluoroethylene (ECTFE), polyvinylidene (di)fluoride (PVDF), and combinations thereof.

6. The photovoltaic module of claim 1, wherein the first TPU layer has a thickness between 0.2 mm and 1.2 mm.

7. The photovoltaic module of claim 1, wherein the first encapsulation layer comprises a material selected from the group consisting of ethylene vinyl acetate (EVA) copolymer, polyolefin elastomer (POE), polyvinyl butyral (PVB), thermoplastic polyolefin elastomer (TPO), and combinations thereof.

8. The photovoltaic module of claim 1, wherein the first encapsulation layer has a thickness between 0.2 mm and 1.2 mm.

9. The photovoltaic module of claim 1, further comprising a frame in contact with one or more edges of the first polycarbonate layer, the first TPU layer, the first encapsulation layer, and the solar cell.

10. The photovoltaic module of claim 1, wherein the solar cell converts energy having a wavelength from about 300 nm to about 1800 nm to electricity.

11. The photovoltaic module of claim 1, wherein the first polycarbonate layer has an average transmittance of light from 400 nm to 1100 nm of at least 85% at a layer thickness of 3 mm or less.

12. The photovoltaic module of claim 1, further comprising:
a second polycarbonate layer having a first major surface and a second major surface;
a second thermoplastic polyurethane (TPU) layer having a first major surface and a second major surface, wherein the first major surface of the second TPU layer is in contact with the second major surface of the second polycarbonate layer; and
a second encapsulation layer having a first major surface and a second major surface, wherein the first major surface of the second encapsulation layer is in contact with the second major surface of the second TPU layer, and the second major surface of the second encapsulation layer is in contact with the second major surface of the solar cell.

13. The photovoltaic module of claim 12, wherein the second polycarbonate layer comprises a UV stabilizer.

14. The photovoltaic module of claim 13, wherein the UV stabilizer of the second polycarbonate layer is selected from the group consisting of benzotriazoles, benzophenones, organic nickel compounds, and combinations thereof.

15. The photovoltaic module of claim 12, further comprising a second anti-abrasion layer having a first major surface and a second major surface, wherein the second major surface of the second anti-abrasion layer is in contact with the first major surface of the second polycarbonate layer.

16. The photovoltaic module of claim 15, wherein the second anti-abrasion layer comprises a material selected from the group consisting of fluoropolymers, epoxy, polyphenylene sulfide (PPS), ethylene tetrafluoroethylene (ETFE), ethylene-chlorotrifluoroethylene (ECTFE), polyvinylidene (di)fluoride (PVDF), and combinations thereof.

17. The photovoltaic module of claim 12, wherein the second TPU layer has a thickness between 0.2 mm and 1.2 mm.

18. The photovoltaic module of claim 12, wherein the second encapsulation layer comprises a material selected from the group consisting of ethylene vinyl acetate (EVA) copolymer, polyolefin elastomer (POE), polyvinyl butyral (PVB), thermoplastic polyolefin elastomer (TPO), and combinations thereof.

19. The photovoltaic module of claim 12, wherein the second encapsulation layer has a thickness between 0.2 mm and 1.2 mm.

20. The photovoltaic module of claim 12, further comprising a frame in contact with one or more edges of the second polycarbonate layer, the second TPU layer, the second encapsulation layer, and the solar cell.

21. A method of building a photovoltaic module comprising:
positioning a first encapsulation layer having a first major surface and a second major surface and a solar cell having a first major surface and a second major surface such that the first major surface of the solar cell is in contact with the second major surface of the first encapsulation layer, wherein the first encapsulation layer comprises silicone, thermoplastic silicone elastomer (TPSE), ionomers, and combinations thereof;
positioning a first thermoplastic polyurethane (TPU) layer having a first major surface and a second major surface, such that the first major surface of the first encapsulation layer is in contact with the second major surface of the first TPU layer;
positioning a first polycarbonate layer having a first major surface and a second major surface such that the first major surface of the first TPU layer is in contact with the second major surface of the first polycarbonate layer; and
laminating the first polycarbonate layer, the first TPU layer, the first encapsulation layer, and the solar cell.

22. The method of claim 21, wherein the first TPU layer and the first encapsulant layer are coextruded.

23. The method of claim 21, wherein the first encapsulation layer comprises a material selected from the group consisting of ethylene vinyl acetate (EVA) copolymer, polyolefin elastomer (POE), polyvinyl butyral (PVB), thermoplastic polyolefin elastomer (TPO), and combinations thereof.

24. The method of claim 21, further comprising positioning a first anti-abrasion layer having a first major surface and a second major surface such that the second major surface of the first anti-abrasion layer is in contact with the first major surface of the first polycarbonate layer.

25. The method of claim 24, wherein the first anti-abrasion layer comprises a material selected from the group consisting of fluoropolymers, epoxy, polyphenylene sulfide (PPS), ethylene tetrafluoroethylene (ETFE), ethylene-chlorotrifluoroethylene (ECTFE), polyvinylidene (di)fluoride (PVDF), and combinations thereof.

26. The method of claim 21, further comprising, prior to the laminating:
positioning a second encapsulation layer having a first major surface and a second major surface such that the second major surface of the solar cell is in contact with the second major surface of the second encapsulation layer;
positioning a second thermoplastic polyurethane (TPU) layer having a first major surface and a second major surface, such that the first major surface of the second encapsulation layer is in contact with the second major surface of the second TPU layer; and
positioning a second polycarbonate layer having a first major surface and a second major surface such that the first major surface of the second TPU layer is in contact with the second major surface of the second polycarbonate layer.

27. The method of claim 26, wherein the second TPU layer and the second encapsulant layer are coextruded.

28. The method of claim 27, wherein the second encapsulation layer comprises a material selected from the group consisting of ethylene vinyl acetate (EVA) copolymer, polyolefin elastomer (POE), polyvinyl butyral (PVB), thermoplastic polyolefin elastomer (TPO), and combinations thereof.

29. The method of claim 26, further comprising, prior to the laminating, positioning a second anti-abrasion layer having a first major surface and a second major surface such that the second major surface of the second anti-abrasion layer is in contact with the first major surface of the second polycarbonate layer.

30. The method of claim 29, wherein the second anti-abrasion layer comprises a material selected from the group consisting of fluoropolymers, epoxy, polyphenylene sulfide (PPS), ethylene tetrafluoroethylene (ETFE), ethylene-chlorotrifluoroethylene (ECTFE), polyvinylidene (di)fluoride (PVDF), and combinations thereof.

31. The method of claim 21, wherein the lamination comprises 30 minutes of vacuum.

32. The method of claim 21, wherein the lamination is performed at a temperature of about 130° C.

33. The method of claim 21, wherein the lamination is performed at a pressure of about 1400 mbar.

34. The method of claim 21, wherein the lamination comprises encapsulant lamination, flatbed lamination, hot melt lamination, or any combination thereof.

35. The method of claim 21, further comprising framing the photovoltaic module.
